(19) United States
(12) Patent Application Publication
(10) Pub. No.: US 2026/0255503 A1
(43) Pub. Date: Aug. 27, 2026

(54) KITCHEN APPLIANCE

(71) Applicant: Breville Pty Limited, Alexandria, NSW (AU)

(72) Inventors: David DAVENPORT, Alexandria, NSW (AU); Eddie SIU, Alexandria, NSW (AU); Richard Lehonde HOARE, Alexandria, NSW (AU); Joshua Matthew MORABITO, Alexandria, NSW (AU)

(21) Appl. No.: 18/879,364

(22) PCT Filed: Jun. 30, 2023
(86) PCT No.: PCT/AU2023/050611

§ 371 Date: Dec. 27, 2024

(30) Foreign Application Priority Data
Jun. 30, 2022 (AU) 2022901832

(51) Int. Cl. H05K 5/00; A47J 31/52; G06F 3/0354; H05K 5/02

(52) U.S. Cl. CPC H05K 5/0018; A47J 31/52; G06F 3/03547; H05K 5/0217

(57) ABSTRACT

Disclosed is a display assembly (200) suitable for a kitchen appliance (1), the assembly (200) comprising: a display panel (201) having an exterior surface (203) featuring a display zone (204) for presenting visual display information (207) from and optical output (210) of a display output device (209), wherein at least a portion of the exterior surface (203) of the display panel (201) comprises a curved surface, and at least a portion of the interior surface (202) is planar.

### FIELD

The technology relates to kitchen appliances with visual displays.

### BACKGROUND

Many kitchen appliances include visual displays to communicate information to a user, as well as to facilitate receiving user commands. For example, a visual display may be used to present options for operating the appliance from which a user may make a selection from.

It is often the case that kitchen appliances have limited suitable space on which to place visual displays and user controls. Visual displays and user controls may also interfere with the aesthetic and functional design of the appliance, for example, by interrupting contours and creating a cluttered user interface that detracts from the user experience and ease of use. The materials used by visual displays and controls may also poorly contrast with materials used to form the appliance, which may pose further complications in the industrial design of appliances. Accordingly, it is often difficult to implement displays and controls in certain appliances, particularly more sophisticated displays and controls.

Displays and controls may also pose difficulties to cleaning, for example, by creating small gaps and crevices that may collect debris. Similarly displays and controls may create points of ingress for material such as food splatter, which may damage the kitchen appliance.

There is a need to improve the visual displays and/or user controls for use with kitchen appliances.

### SUMMARY

It is an object of the present invention to at least substantially address one or more of the above disadvantages, or at least provide a useful alternative.

In accordance with an aspect of the invention, there is provided a kitchen appliance comprising a display assembly, the assembly comprising: a display panel having an exterior surface featuring a display zone for presenting visual display information from and optical output of a display output device, wherein at least a portion of the exterior surface of the display panel comprises a curved surface, and at least a portion of the interior surface is planar.

In embodiments, said assembly is a dead front assembly.

In embodiments said display zone has one or more of: a low transmission ratio, a highly reflective visual characteristic, or a metallic ambient appearance when not displaying visual display information.

In embodiment the low transmission ratio, a highly reflective visual characteristic, or a metallic ambient appearance when not displaying visual display information is provided by a coating on an exterior surface of the display panel.

In embodiments the coating is a non-conductive in mold decoration (IMD) film or a hot stamped film.

In embodiments the IMD film has a transmission ratio of about 10% to about 40%, and has an ambient appearance simulating stainless steel.

In embodiments the display panel thickness varies transverse along the display zone perpendicular to the thickness dimension by a ratio of equal or less than about 0.025.

In embodiments the exterior surface had a compound curvature, and wherein the display panel thickness varies along a first perpendicular transverse direction of the display zone by a ratio of about 0.02, and along a second perpendicular transverse direction of the display zone by a ratio of about 0.01.

In embodiments the kitchen appliance also includes a touch sensitive layer applied to the planar interior surface.

In embodiments the touch sensitive layer is flat and substantially rigid.

In embodiments the touch sensitive layer is affixed to the interior surface.

In embodiments the touch sensitive layer is optically bonded to the interior surface.

In embodiments the touch sensitive layer is affixed to the surface using double sided tape.

In embodiments tinted resin is used for optical bonding.

In embodiments brightness of the display zone is configured as between about 150 nits to about 500 nits.

In embodiments brightness of the display zone is configured about 250 nits.

In embodiments the optical display device has a backlight illuminance of less than about 2000 nits.

In embodiments the kitchen appliance also includes a chassis having secondary features for supporting the display panel.

In embodiments the secondary features include one or more of supporting ribs or screw tubes.

In embodiments clip features are used to removably attached the chassis to the display panel.

In embodiments the display zone has an appearance simulating surrounding portions of the kitchen appliance.

In embodiments the display zone has a first state without any visual display information from the display output device; a second state where the visual display information includes an indicia representing a power on operation; a third state with visual display information showing selectable modes of operation; and fourth state with the visual display information relating to the selected mode of operation.

In embodiments the display zone is configured to present a menu of selections available to a user, and upon selection from said menu, present indicia related to that selection.

In embodiments the display output device is an LED display.

In embodiments the display output device is an LCD display.

In embodiments the display output device is a thin film transistor (TFT) display.

In embodiments the display output device is an in plane switching (IPS) display.

In embodiments the display output device is an OLED display.

In embodiments the display output device is a negative display wherein black pixels are un-energised.

Also disclosed is a dead front display for a kitchen appliance as defined in the above aspect and embodiments.

Also disclosed is a deadfront display assembly for a kitchen appliance comprising: a display panel having an exterior surface featuring a display zone for presenting visual display information from optical output of a display output device; wherein said display zone has one or more of: a low transmission ratio, a highly reflective visual characteristic, or a metallic ambient appearance when not displaying visual display information.

In embodiments the low transmission ratio, a highly reflective visual characteristic, or a metallic ambient appearance when not displaying visual display information is provided by a coating on an exterior surface of the display panel.

In embodiments the coating is a non-conductive in mold decoration (IMD) film.

In embodiments the IMD film has a transmission ratio of about 10% to about 40%, and has an ambient appearance simulating stainless steel.

In embodiments at least a portion of the exterior surface corresponding to the display zone has a curved contour.

In embodiments the display panel has an interior surface, wherein at least a portion of the interior surface corresponding to the display zone is planar.

In embodiments the display panel thickness varies transverse along the display zone perpendicular to the thickness dimension by a ratio of equal or less than about 0.025.

In embodiments the exterior surface had a compound curvature, and wherein the display panel thickness varies along a first perpendicular transverse direction of the display zone by a ratio of about 0.02, and along a second perpendicular transverse direction of the display zone by a ratio of about 0.01.

In embodiments the display assembly further includes a touch sensitive layer applied to the planar interior surface.

In embodiments the touch sensitive layer is flat and substantially rigid.

In embodiments the touch sensitive layer is optically bonded to the interior surface.

In embodiments tinted resin is used for optical bonding.

In embodiments brightness of the display zone is configured as between about 150 nits to about 500 nits.

In embodiments brightness of the display zone is configured about 250 nits.

In embodiments the optical display device has a backlight illuminance of less than about 2000 nits

In embodiments the dead front display assembly further includes a chassis having secondary features for supporting the display panel.

In embodiments the secondary features include one or more of supporting ribs or screw tubes.

In embodiments clip features are used to removably attached the chassis to the display panel.

In embodiments the display output device is an LED display.

In embodiments the display output device is an LCD display.

In embodiments the display output device is a thin film transistor (TFT) display.

In embodiments the display output device is an in plane switching (IPS) display.

In embodiments the display output device is an OLED display.

In embodiments the display output device is a negative display wherein black pixels are un-energised.

Also disclosed is a kitchen appliance including the above disclosed dead front display panel and its embodiments, wherein the display zone has a metallic appearance simulating proximal portions of the kitchen appliance outer housing formed from a metallic material.

Also disclosed is a kitchen appliance including the above disclosed dead front display panel and its embodiments, wherein the display zone has a first state without any visual display information from the display output device; a second state where the visual display information includes an indicia representing a power on operation; a third state with visual display information showing selectable modes of operation; and fourth state with the visual display information relating to the selected mode of operation.

In embodiments the display zone is configured to present a menu of selections available to a user, and upon selection from said menu, present indicia related to that selection.

Also disclosed is a kitchen appliance comprising: an outer housing formed from at least one housing material; a display panel; and, a display output device having: an energized state producing an optical output incident on an interior surface of the display panel for viewing from an exterior surface of the display panel thereby defining a display zone of the exterior surface of the display panel; and, an unenergized state wherein the display zone has an ambient appearance like that of the at least one housing material.

In embodiments the display zone has a substantially opaque ambient appearance.

In embodiments the display zone has a metallic ambient appearance.

In embodiments the display zone has a diffusely reflective ambient appearance.

In embodiments the display zone has an ambient appearance of stainless steel.

In embodiments the display zone has an ambient appearance of brushed stainless steel.

In embodiments the display zone has an ambient appearance of polished stainless steel.

In embodiments the display panel has a transmittance ratio of between about 10% to about 20%.

In embodiments the display panel has a transmittance ratio of between about 11% to about 19%.

In embodiments the display panel has a transmittance ratio of between about 12% to about 18%.

In embodiments the display panel has a transmittance ratio of between about 13% to about 17%.

In embodiments the display panel has a transmittance ratio of between about 14% to about 16%.

In embodiments the display panel has a transmittance ratio of between about 15.5 and about 16.5%.

In embodiments the display panel has a transmittance ratio of about 16%.

In embodiments the display output device is an electronic visual display.

In embodiments the display output device is an LED display.

In embodiments the display output device is an LCD display.

In embodiments the display output device is a thin film transistor (TFT) display.

In embodiments the display output device is an in plane switching (IPS) display.

In embodiments the display output device is an OLED display.

In embodiments the display output device is a negative display wherein black pixels are un-energised.

In embodiments the luminance from the display zone is between about 150 cd/m² to about 300 cd/m².

In embodiments the luminance from the display zone is between about 175 cd/m² to about 275 cd/m².

In embodiments the luminance from the display zone is between about 200 cd/m² to about 250 cd/m².

In embodiments the kitchen appliance further comprises a touch-sensitive layer optically bonded to the interior surface of the display panel such that the display zone is a touch screen.

In embodiments the display panel is mounted to a chassis.

In embodiments the display panel is mounted to the chassis by an adhesive layer.

In embodiments the display output device is mounted to the chassis opposite the display panel.

In embodiments the chassis has one or more apertures providing optical communication between the display output device and the display panel.

In embodiments the chassis has an exterior face configured with a curvature such that the display mounted thereto is similarly configured with the curvature.

In embodiments the radius of curvature is about a horizontal axis.

In embodiments the chassis has a maximum thickness of between about 5 mm to about 7 mm.

In embodiments the chassis has a maximum thickness of between about 4.5 mm to about 5.8 mm.

In embodiments the chassis has a maximum thickness of about 5.8 mm.

In embodiments the chassis has a minimum thickness of between about 1 mm to about 3 mm.

In embodiments the chassis has a minimum thickness of between about 1.2 mm to about 2.2 mm.

In embodiments the chassis has a minimum thickness of about 2.2 mm.

In embodiments the kitchen appliance includes a plurality of display output devices corresponding to a plurality of display zones.

In embodiments, the chassis has a plurality of apertures corresponding to the plurality of display output devices.

In accordance with an aspect of the present invention, there is provided a display assembly for a kitchen appliance comprising: a display panel with transmittance ratio of about 16%; and, a display output device producing optical output with luminance of at least 1000 cd/m² (nits) incident on the display panel.

### BRIEF DESCRIPTION OF THE DRAWING

Preferred embodiments of the present invention will now be described by way of example, with reference to the accompanying drawings, wherein:

FIG. 1 is a schematic top front perspective view of a kitchen appliance according to an embodiment of the present invention;

FIG. 2 is a schematic front view of the kitchen appliance of FIG. 1 with display zones visible;

FIG. 3 is a schematic front view of the kitchen appliance of FIG. 1 with display zones indistinguishable from non-display portions of the display panel;

FIG. 4 is a schematic front view of a kitchen appliance according to an embodiment of the present invention with display zone of the display panel indistinguishable from non-display portions;

FIG. 5 is a schematic front view of a kitchen appliance of FIG. 4 with display zone exhibiting visual display information;

FIG. 6 is schematic front view of a kitchen appliance according to an embodiment of the present invention with a display zone exhibiting visual display information;

FIG. 7 is a schematic view of an embodiment of a display panel with visual display information exhibited on the display zone;

FIG. 8 is a schematic view of an embodiment of a partially assembled display assembly;

FIG. 9 is a partial schematic view of the display assembly of FIG. 8 with energised display output devices producing optical output;

FIG. 10 is a partial schematic view of an embodiment of a display assembly according to the present invention;

FIG. 11 is an schematic exploded perspective view of a display assembly according to the present invention;

FIG. 12 is a schematic perspective view of an assembled display assembly of FIG. 11

FIG. 13 is a schematic perspective cutaway view of the FIG. 12 display assembly taken along axis A-A;

FIG. 14 is a schematic alternative perspective view of the display assembly of FIG. 12;

FIG. 15 is a schematic exploded perspective view of an embodiment of a display assembly;

FIG. 16 is a schematic perspective view of a partially assembled display assembly;

FIG. 17 is a schematic perspective sectional view of the FIG. 16 display assembly taken along line A-A;

FIG. 18 is an alternative schematic perspective view of the FIG. 16 display assembly;

FIG. 19 is a schematic sectional exploded view of an embodiment of a display assembly in accordance with the present invention;

FIG. 20 is a schematic rear perspective view of the display assembly of FIG. 19;

FIG. 21 is a schematic front perspective view of the display assembly of FIG. 19;

FIG. 22 is a schematic side perspective sectional view of the display assembly of FIG. 19;

FIG. 23 is a schematic top perspective sectional view of the display assembly of FIG. 19;

FIG. 24 is a schematic perspective sectional view of a display panel in accordance with the display assembly of claim 19 in exploded format with a display output device;

FIG. 25 is a schematic representation of a display assembly with shadowed optical output.

### DETAILED DESCRIPTION

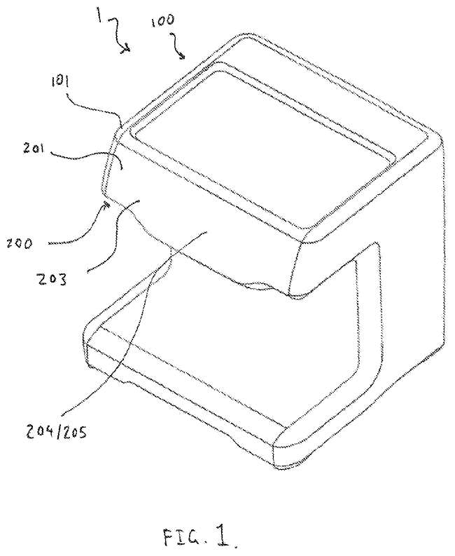

Referring to FIG. 1, shown is a kitchen appliance (1), specifically, an espresso machine (1), having an outer housing (101) defining a body (100). The outer housing (101) is formed from one or more outer housing (101) materials. In an example embodiment, the outer housing (101) may be formed wholly or primarily of stainless steel, although other materials may also be used, for example various plastics, either alone or in combination.

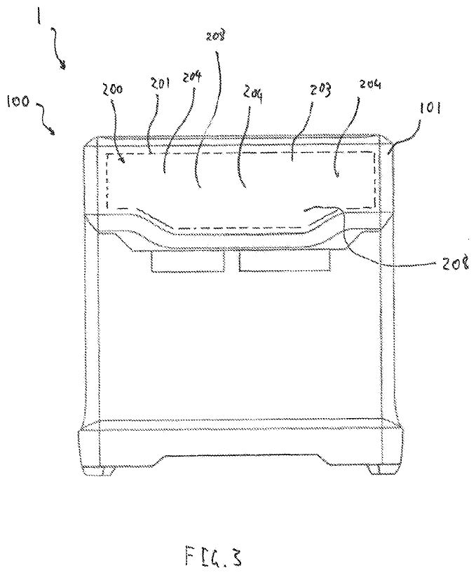

An upper, forward-facing portion of the outer housing (101) is configured as a dead front display panel (201) having display zones (204) where visual display information (207) can be visually exhibited, as disclosed in the embodiments herein. Under ambient conditions without any visual display information (207) shown in the display zone (204), the display zone (204) appears identical, or at least substantially identical to adjacent non-display portions (208), thus providing a seamless impression as shown in FIGS. 3 and 4, for example. In this context, ambient conditions include typical room lighting and when viewed no closer than a normal operating distance from the machine (1).

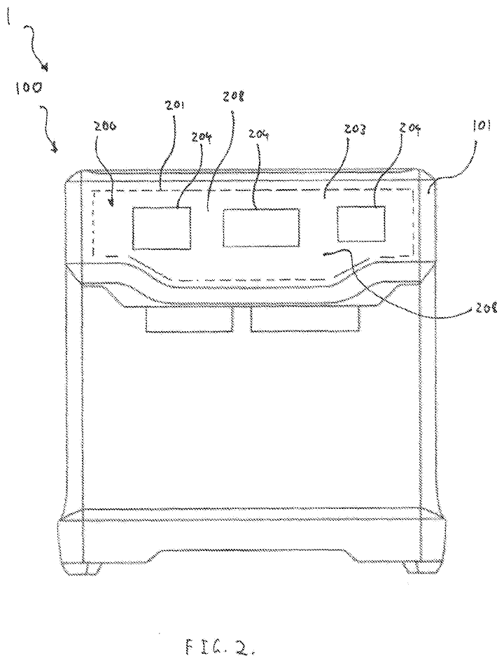

The display zones (204) are associated with display output devices (209) mounted internally of the body (100). In an example embodiment, the display output device (209) is a thin film transistor (TFT) electronic display, though other options will be apparent to the person skilled in the art. The display output device (209) has an energized state producing optical output (210) defining visual display information (207) to be exhibited in the display zone (204). The display output device (209) is arranged such that its optical output (210) is incident upon an interior surface (202) of the display panel (201) whereby it at least partially transmits so as to be visible from the exterior surface (203) of the display panel (201) thereby defining the display zone (204) as shown in FIGS. 2 and 5, for example. The display panel (201) and the display output device (209) are components of a display assembly (200).

FIG. 2 shows an example embodiment espresso machine (1) with three display output devices (209) energized to transmit visual display information (207) to three display zones (204) within the display panel (201). FIG. 3 shows the espresso machine (1) where the display output devices (209) are not energized and thus not producing optical output (210); accordingly, not visual display information (207) is exhibited in the display zone (204). By this arrangement, the display zone (204) is indiscernible from the non-display portions (208) of the display panel (201), such that the display panel (201) gives the impression seamless or continuous impression. Otherwise stated, the ambient appearance of the display zone (204) is like that of one of the outer housing (101) materials. Furthermore, the unenergized display output device (209) is not visible, or at least not substantially visible.

In the energized state of FIGS. 2 and 4, for example, the display zone (204) of the display panel (201) appears translucent, allowing optical output (210) from the display output device (209) incident on the interior surface (202) to propagate through to the exterior surface (203). In the unenergized state of FIGS. 3 and 5, for example, the exterior surface (203) of the display panel (201) including the display zones (204) appears opaque. The display zone (204) acts as if formed from a translucent material when the display output device (209) is energized to transmit visual display information (207), and acts as if formed from an opaque material when the display output device (209) is not energized.

Alternatively stated, when the display output device (209) is in an unenergized state, the display zone (204) has an ambient appearance at least substantially similar to an adjacent or proximal portion of the outer housing (101), such as a non-display portion (208) of the display panel (201). By this arrangement, the display zone (204) is only substantially discernible when in use with the display output device (209) energized. Otherwise, it is disguised as part of the outer housing (101), for example, appearing as an opaque surface such as stainless steel. The ambient appearance is the impression given to a user of the machine at a normal operating distance from the machine (1) under typical lighting conditions. The display zones (204) are therefore of the type known as dead-front displays, where the display output device (209) is hidden behind the display panel (201) until energised. The visual display information (207) appears as emitted from the exterior surface (203) of the display panel (201), rather than being generated internally from the panel (201). Only sections of the display zone (204) receiving optical output (210) from the energized display output device (209) appear to act as translucent to exhibit visual display information (207); parts of the display zone (204) not receiving optical output (210) and thus not exhibiting visual display information (207) act opaque and appear as ordinary housing (101) material.

FIGS. 4 and 5 are embodiments having two main display zones (205) disposed about a central vertical axis of the display panel (201), and a secondary display zone (206) with visual display information (207) in the form of a power button. Here the outer hosing (101) material is stainless steel. In an example embodiment, the kitchen appliance (1) may feature a proximity sensor (212) adapted to trigger the power button icon being displayed as visual display information (207) on the secondary display zone (206). The secondary display zone (206) may be part of a display assembly (200) having a touch-sensor layer (211), such that a user may press the illuminated power button on the secondary display zone (206) to initiate a change of state in the kitchen appliance (1). Such a change of state may be a start-up sequence which may involve, for example, purging lines, heating water or any other function relevant to the kitchen appliance (1). The change of state may also energize one or more of the other display zones (204), with the corresponding portion of the display panel (201) appearing to the user as transforming from opaque stainless steel to a dead-front electronic display presenting visual display information (207).

Any particular display zone (204), or portion of the display zone (204) may be configured to only exhibit visual display information (207) as required, such that those display zones (204) or portions of display zones (204) appear as the outer housing (101) material when not in use, for example stainless steel. As previously stated, the espresso machine (1) may have a first state where the display panel (201) appears as ordinary housing (101) material, and none of the display zones (204) are discernible as shown in FIG. 4. The machine (1) may have a second state where only a power button icon is exhibited on any of the display zone (204). This second state may be triggered by a proximity sensor (212) detecting a user is nearby or is approaching the machine and thus detecting an increasingly proximal position over a time period. In alternative embodiments, the espresso machine (1) may be configured to detect certain gestures to trigger the second state, or the machine (1) may simply have a physical power button.

The machine (1) may have a third state triggered by actuation of the power button. The illuminated power button icon may change colour to mark the transition between these second and third states. The third state may involve visual display information (207) being exhibited on one of the two main display zones (205) of FIG. 5, such that it would appear to transition from opaque outer housing (101) material to an illuminated electronic display. In this third state the other of the two main display zones (205) may not be required and thus remains unenergized so as to appear as opaque outer housing (101) material to a user of the machine (1). The visual display information (207) exhibited on the energised primary main display zone (205) may correspond to icons of various beverages, or other operational instructions such as opening menus, cleaning functions, settings etc. The display assembly (200) associated with this display zone (204) may include a touch-sensor layer (211) such that a user can swipe the display zone (204) to cycle through the list of available beverages to select the desired beverage by touching the corresponding icon.

Selection of the desired beverage may initiate a fourth state, where the other of the main display zones (205) illuminates to transition for appearing as ordinary stainless steel outer housing (101) material to exhibiting visual display information (207) from the exterior surface (203) of the corresponding portion of the display panel (201). This visual display information (207) may relate to instructions for preparing the selected beverage and thus not required until the machine (1) entered the fourth state. These instructions may be in the form of coloured animated graphics or video representations of how the machine is to be operated to produce the selected beverage. In an embodiment, the display assembly (200) corresponding to this display zone (204) for instructions may not have touch-sensitive functionality, or may have limited touch-sensitive functionality, for example, with only a portion having a touch-sensor layer (211).

When the machine (1) is in the fourth state, only visual display information (207) corresponding to instructions for preparing the selected beverage may be required. Accordingly, the machine (1) may be configured to de-energise the display zone (204) corresponding to operating mode with icons of various beverages, as a selection has been made. This display zone (204) would thus appear to transform back to being formed of ordinary outer housing (101) material. Alternatively, this display zone (204) may exhibit visual display information (207) relevant to the fourth state. By way of a non-limiting example embodiment, such visual display information (207) may involve only a portion of the display zone (204) illuminated to exhibit a button icon, with the remainder of the display zone (204) appearing as stainless steel outer housing (101) material. Such a button icon may be pressed to return the machine (1) into the third state so an alternative selection may be made.

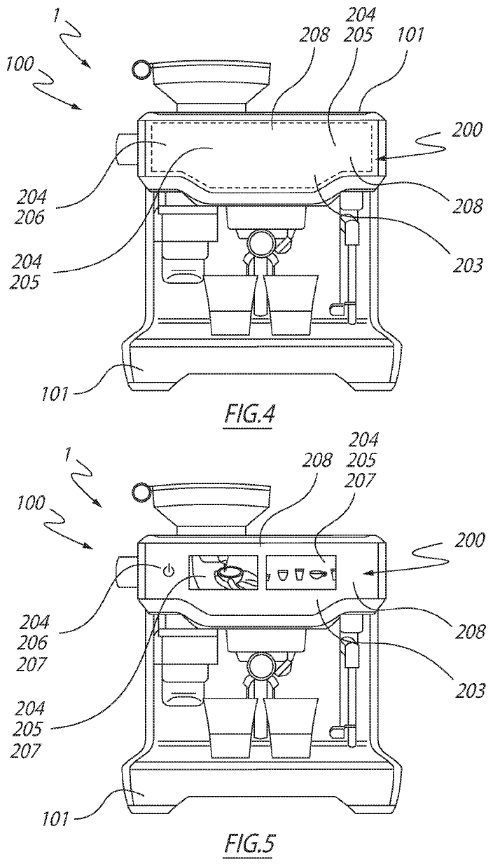

FIG. 6 shows an alternative embodiment where the display panel (201) comprises one display zone (204). The single display zone (204) may be sized to occupy the entire exterior surface (203) of the display panel (201), or any part thereof. The depicted display zone (204) exhibits visual display information (207) corresponding to the third state of the machine (1) as hereinbefore described. Upon selection of the desired beverage, the visual display information (207) exhibited on the display zone (204) may change to instructions for preparing the desired beverage, i.e. corresponding to the fourth state as hereinbefore described.

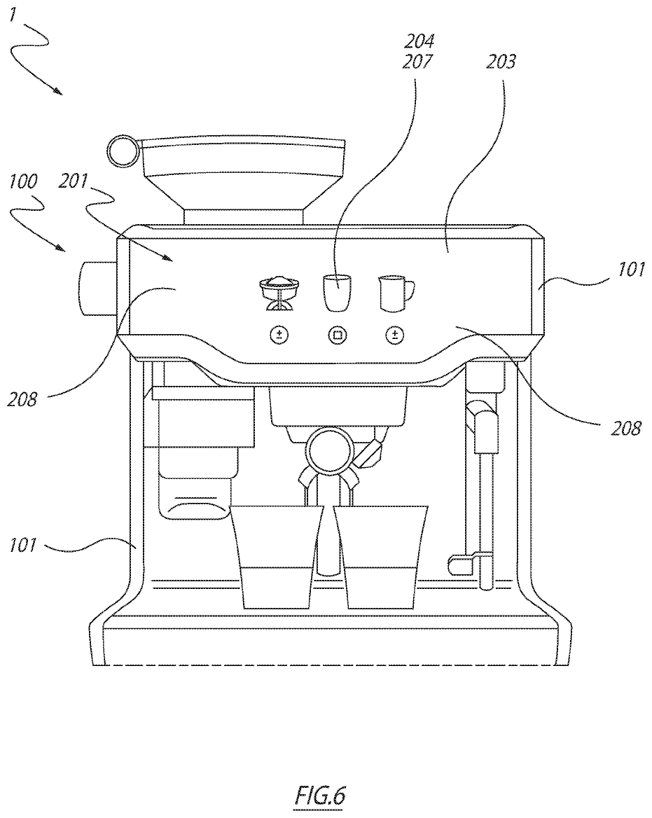

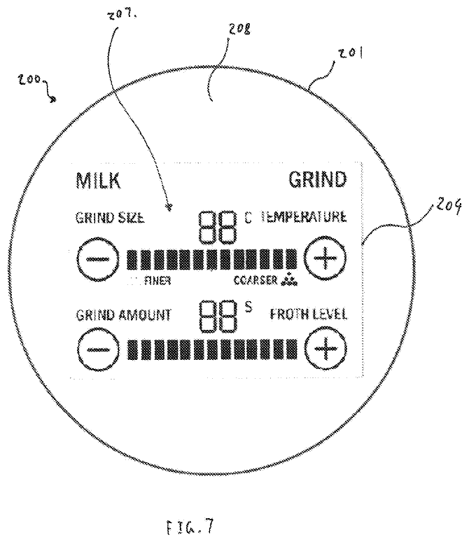

Shown in FIG. 7 is a circular display panel (201) associated with a rectilinear display zone (204) defined by a display output device (209) of commonly available rectilinear proportions. As the un-energised portions of the display output device (209) are not visible through the opaque acting exterior surface (203) of the display panel (201), the display zone (204) may give the impression of spanning the entire circular footprint of the display panel (201) despite only spanning a rectilinear subset of the area. Accordingly, a display assembly (200) may be provided as having the impression of a circular display zone (204) despite using an ordinary rectangular-shaped display output device (209); said assembly having use for presenting visual display information (207) usually associated with round dials, for example.

An example partial assembly of a display assembly (200) including display output devices (209) mounted to a chassis (213) is shown in FIGS. 8 and 9. A larger central display output device (209) is configured to correspond to a main display zone (205) occupying a central position of the display panel (201), and smaller display output devices are configured to correspond to two secondary display zones (206) flanking the main display zone (205). In an example non-limiting embodiment, a single HY 4635-No68 touch controller with 2IC interface forms the touch-sensor layer (211) for all three display output devices (209). The display output device (209) corresponding to the main display zone (205) has a horizontal dimension of about 114 mm and a vertical dimension of about 65 mm, and is associated with a 5.0″ IPS TFT (mipi) display output device (209) having 1280×750 resolution and a MIPI interface of four lanes. The illumination module (221) backlight driving conditions may include: 6×3=18 LEDs, IF=6×50 mA=300 mA, Voltage: 9V (8-10V). The main display zones (205) may be primarily used to display a “carousel” of icons which may be swiped through to make the desired selection. These icons may correspond to operating modes of the machine corresponding to particular beverages, or some particular menu options, for example. Optical output (210) of example schematic representations of icons are shown in relief in FIG. 9.

The display output devices (209) corresponding to secondary display zones (206) may have a horizontal dimension of 52 and a vertical dimension of 39 mm. One of the secondary display zones (206) may be associated with a 2.4″ segmented LED display output device (209) having a 78 LEDs matrix with 18 pins and 4× touch points in segmented LED display in accordance to a non-limiting example embodiment. This display output device (209) may produce optical output (210) corresponding to respective time and/or temperature data with a bar graph that moves according to touch, as show in relief in FIG. 9.

The display output device (209) corresponding to the other of the secondary display zones (206) may be associated with a 2.4″ TFT with a SPI interface with illumination module (221) backlight conditions of: 2×3=6 LEDs, IF=2×50 mA, Voltage: 8-10V in accordance to a non-limiting embodiment. This display output device (209) may produce optical output (210) corresponding to animated graphics, for example colour video instructions on how to operated the machine to prepare the desired beverage, having associated touch-screen functionality to pause/play the video. The display output device may be used to show images, icons, sensor data, videos and any other indicia or information required. The display output device is a device with a screen that shows a rendered electronic image made up of pixels that are illuminated in a way that distinguishes text and graphic elements.

In embodiments, it is preferable for the display output device to be negative display having a blacker background when power is off, like the TFT IPS display, such that black-space of the display output device is less visible through the display panel, particularly when using illumination modules with high luminance. The advantages of such an arrangement may be apparent to any of the example embodiment display assemblies described herein.

Referring FIG. 10, the display assembly may include a touch-sensor layer to imbue the display zone (204) with touch-screen functionality. The touch-sensor layer (211) may be optically bonded to an interior surface (202) of the display panel (201) corresponding to the display zone (204). The display output device (209) may in turn be optically bonded to an opposing surface of the touch-sensor layer (211) relative the display panel (201). In embodiments, the touch-screen functionality may be associated with haptic feedback.

The exterior surface (203) of the display panel (201) may be curved. In the FIG. 10 embodiment, the exterior surface (203) has a continuous and gently curved contour. The particular contour may advantageously promote diffuse reflections of incident light. Spreading reflected light over a wider range of angles may act to minimize visual display information (207) becoming masked or obscured by reflected light at certain viewing angles as compared to specular reflection as further described herein. In embodiments, anti-reflection coatings may be applied to the display panel. In embodiments, the display panel may have a non-glossy or matte appearance, such as a brushed stainless steel or aluminium appearance, thus having a more diffuse reflective surface rather than a purely spectrally reflective surface.

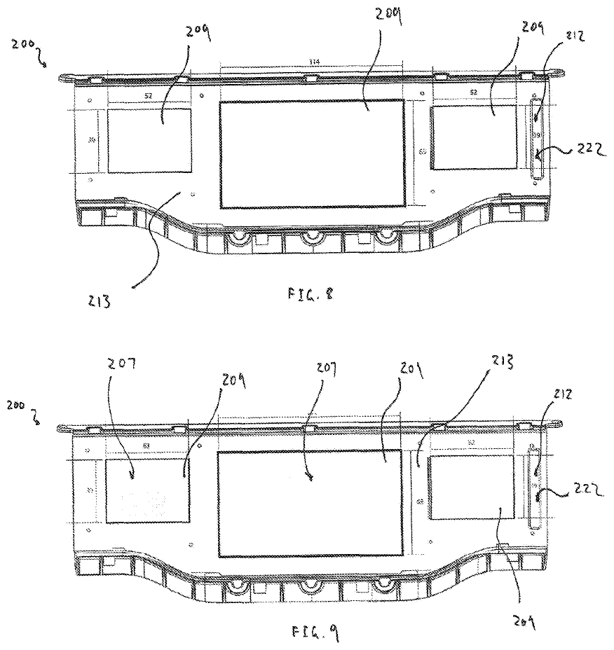

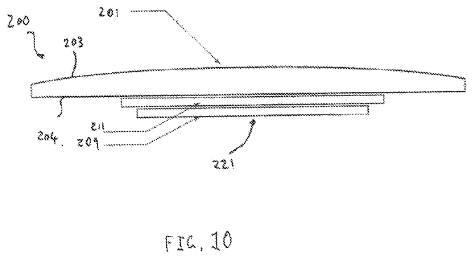

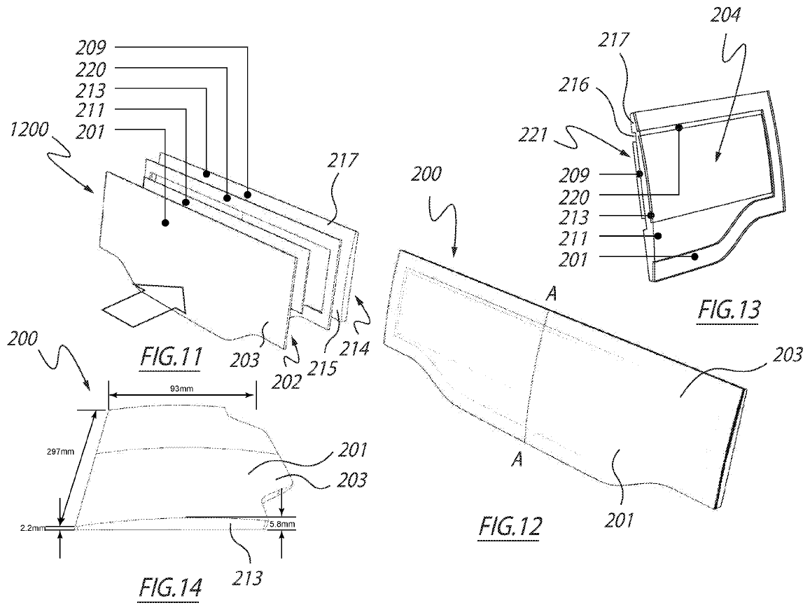

Referring now to FIGS. 11 to 14, shown is a non-limiting example embodiment of a display assembly (200). The display assembly includes a chassis (213) providing structural support for the other components of the display assembly (200). In an example form, the chassis (213) may be formed from transparent nylon, though many other suitable materials will be apparent to the skilled person. An interior-facing surface (214) is recessed (216) to receive the display output device (209). The profile of the recess (216) is rectilinear, presenting a flat surface for receiving a corresponding flat surface of the display output device (209). The recess (216) borders an aperture (218) through which optical output (210) from the display output device (209) passes. FIGS. 11 to 14 involve two display output devices (209) optically bonded to the chassis (213). The two display output devices (209) maybe arranged in side by side relation so as to define contiguous display zones (204) such that visual display information (207) may be linked to give the impression of one large display zone (204). In embodiments, the visual display information (207) on different display output devices (209) may be linked. For example, a scrollable list of icon such as a carousel of selectable icons may be spread over the area of several linked display output devices (209).

An exterior-facing surface (215) of the chassis (213) maybe curved to define the curved surface of the exterior surface (203) as hereinbefore described. An adhesive layer (220) may be applied to the perimeter (217) of the exterior facing surface of the chassis (213). The adhesive layer (220) may be double sided tape, for example 3M VHB double sided tape, though other suitable adhesive layers will be apparent to the person skilled in the art. The double sided tape may start flat, but adopt the contour of the curved exterior surface (203) of the chassis (213) when applied thereto.

As hereinbefore described a touch-sensor layer (211) may be optically bonded to the interior surface (202) of the display panel (201). The touch-sensor layer (211) may be of a smaller dimension to the display panel (201) thereby leaving the perimeter (217) of the display panel (201) free the touch-sensor layer (211) and thus available to contact with the adhesive layer (220) to attach the display panel (201) (and bonded touch-sensor layer (211)) to the chassis (213). Both the display panel (201) and the touch-sensor layer (211) may be formed from a flexible, ordinarily flat material that conforms to the curvature of the chassis (213) when applied thereto, thus defining the curvature of the display panel (201) exterior surface (203).

FIG. 15 shows an alternative embodiment of the display assembly like that of FIGS. 8 and 9 having a centred main display zones (205) flanked by two secondary display zones (206). This embodiment includes a support bracket (219) locating at the interior facing sides of the display output devices (209), the bracket (219) acting as a backing to hold the display output devices (209) in position received by the recesses (216) in the chassis (213).

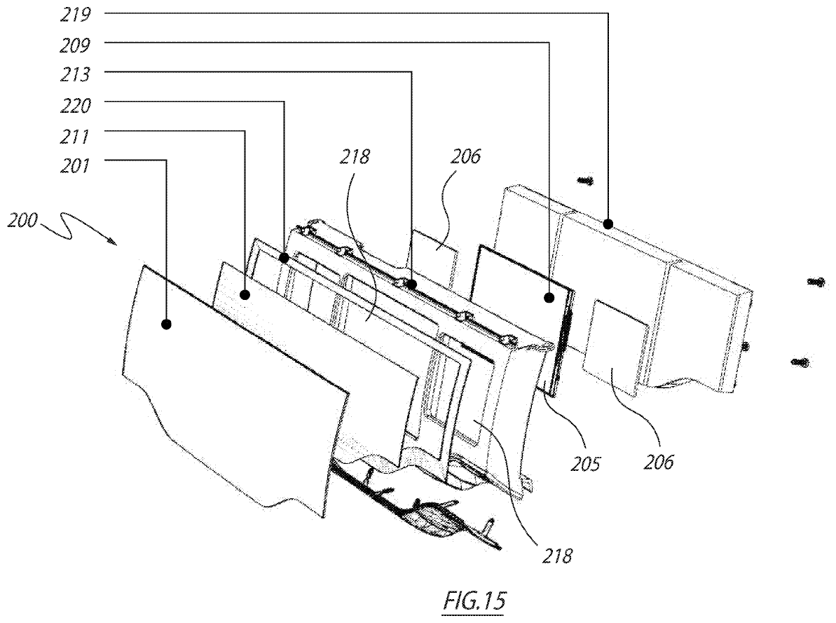

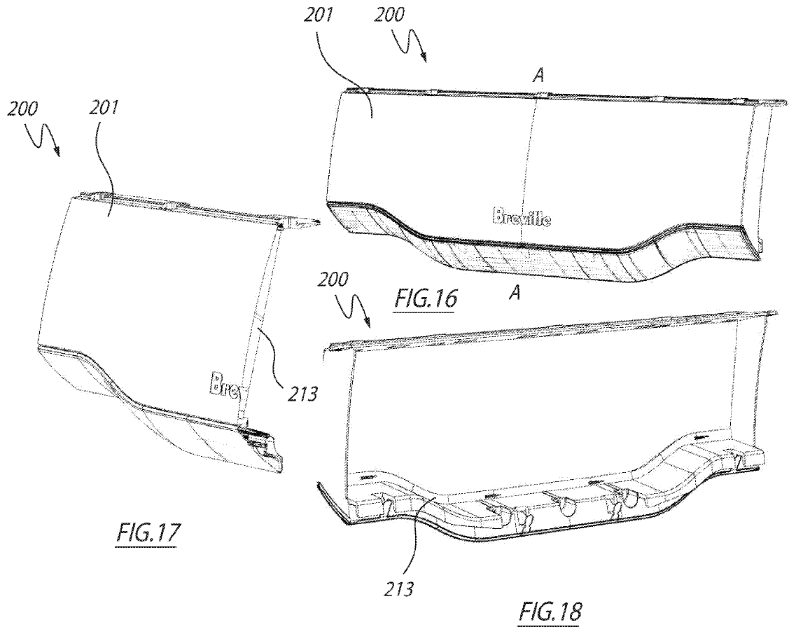

FIGS. 16 to 18 show views of a partially assembled display assembly like that of FIG. 15 absent the display output devices (209) and bracket (219).

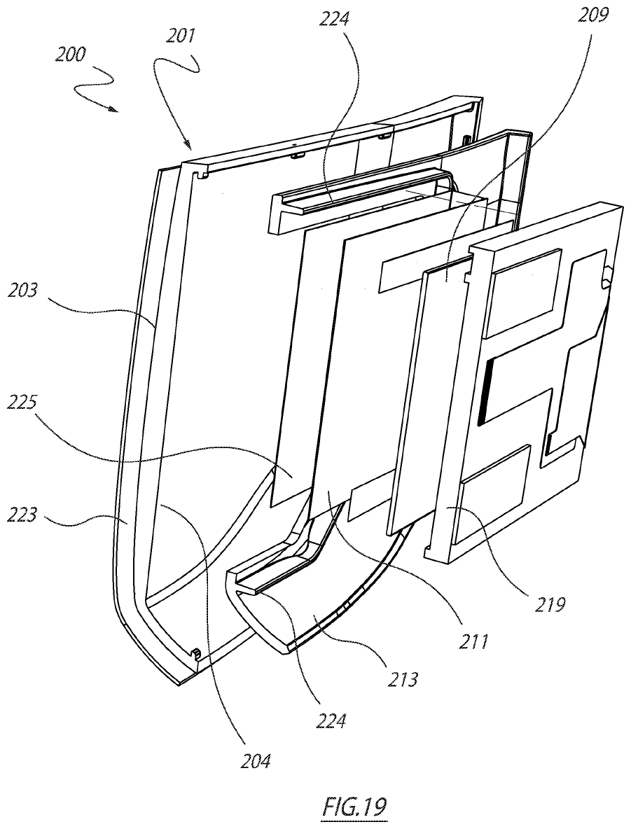

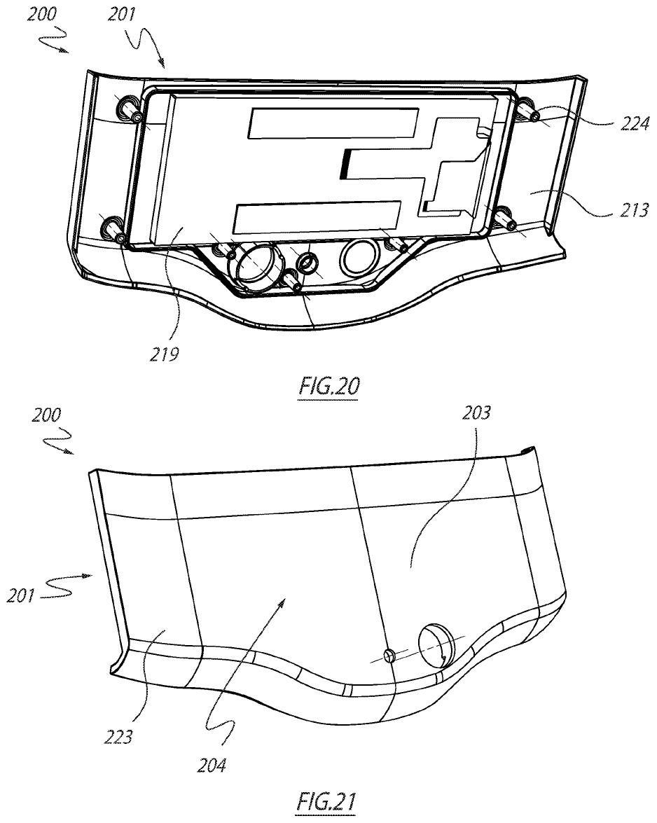

Shown in FIGS. 19 to 24 is another example embodiment of a display assembly (200) also suitable for use in kitchen appliance (1), including but not limited to coffee or espresso machines. This embodiment involves a single display zone (204) associated with a single display output device (209), however it can be adapted for use with display output devices if desired.

Referring to FIG. 19 in particular, the exterior surface (203) of the display panel (201) has a compound curvature, i.e. curved in both the x and y direction. However, the interior surface (202) is substantially planar, such that the interior surface (202) corresponding to the display zone (204) offers a flat surface for association with other components of the display assembly (200). By this arrangement a flat touch sensitive layer (211) and display output device (208) can be applied to the flat interior surface (202) corresponding to the display zone (204), while the actual display zone (204) on the exterior surface (203) presents a compound curvature contour.

The display panel may be advantageously formed from a clear material over which an outer film (223) may be applied to obscure the display output device (209) in an unenergized state so that the display zone (204) in not discernable in the manner of a dead front display. In embodiments, the display panel (201) may be molded in a clear polymer such as polycarbonate, acrylic, acrylonitrile butadiene styrene, nylon or any other suitable material as would be known to the person skilled in the art. In other embodiments, a tint may be applied to the polymer prior to injection molding. In other embodiments, an outer film (223) is not used, but rather the material of the display panel is selected to produce the required ambient surface when no visual display information is present, such as a dark polymer with ambient appearance disguising the interior of the body (100) and the display output device (209) therein.

The chassis (213) in the example embodiment of FIG. 19 is clipped to the display panel (201) using typical clip features. The chassis (213) supports the display panel (201) and may be endowed with secondary features (224) such as screw bosses and strengthening ribs. As features (224) such as screw bosses and strengthening ribs are applied to the clip on chassis (213), the need for such features (224) on the display panel (201) itself can be reduced or even altogether omitted. This may be advantageous to simplify the manufacture of the display panel (201) and reduce the incidence of manufacturing defects, for example, avoiding part sink marks which may affect the appearance of the dead front display zone (204). When the display panel (201) has a highly reflective outer appearance, for example due to use of a highly reflective outer film (223), such defects may have a deleterious effect on the visual display information (207) and may even compromise the dead front effect of the assembly (200).

Further, as the display panel (201) has varying thickness between the interior surface (202) and the exterior (203) surface owing to their opposed flat and curved contours, the manufacture process may already require care to minimize the effect of manufacturing defects such that the otherwise the deleterious effect of the features (224) may have a compounding effect on distorting the visual display information (207). The uneven wall thickness between the interior surface (202) and the exterior surface (203) may result in the flow of molten plastic from thin sections to thicker sections during the molding process, and the polymer material may begin cooling in the thinner sections thereby effectively blocking flow to the thicker sections. Such phenomenon may result in manufacturing defects such as warping and sinking, which may have a deleterious effect on the transmission of the optical output (210) through the display assembly (200) and thus the quality of the visual display information (207) presented on the display zone (204). Certain methods have been identified which may mitigate these effects to improve the optical properties of the display panel (201) having a curved exterior surface (203) and a planar interior surface (202). Increasing the cycle time so that cooling duration can be increased to allow the part being molded to adequately cool after to the injection molding process may minimize the unrestricted movement of the part when cooling outside the tool used for molding. Another method is employing more focused cooling on thicker sections of the part to promote more even cooling between thick to thin sections. Secondary fixtures or jigs may also be used to hold the part in place when cooling.

As the interior surface (202) corresponding to the display zone (204) is flat, a flat touch-sensitive layer (211) can be used, as it must follow the shape of the surface to which it is applied. If the interior surface (202) was curved so that the thickness of the display panel (201) was consistent across the display zone (204), either a curved touch-sensitive layer would need to be considered, or an attempt made to laminate a film-based touch sensitive layer to the interior surface. However, curved and film-based touch sensitive layers are more complicated and expensive than typical flat touch sensitive layers, which have a substantially rigid and non-flexible character, and could not be used for an interior surface (202) having a more complicated compound curvature to match a compound curved exterior surface (203) like that of embodiment of FIGS. 19 to 24.

The touch sensitive layer (211) may be applied to the flat interior (202) using optical bonding. Such optical bonding may involve a process of resin having a high transmissivity between the display panel and the touch sensitive layer. Such a resin may be a clear adhesive forming a thin film having a transmission ratio of about 85% to about 95%. Optical bonding with a resin film having a transmission ratio of about 92% has been successfully used, for example.

Optical bonding (225) may be used to ensure that the touch sensitive layer (211) is as close to the flat interior surface (202) as possible. Ideally, there should be substantially no gap between the interior surface (202) of the display panel (201) and the touch sensitive layer (211) to promote formation of a solid laminate without gaps, pockets of air, dirt nor other defects or debris that may interrupt transmission of the optical output (210) from the display output device (209) through to the display zone (204). Additionally, close proximity between adjacent components of the display assembly (200) including the display panel (201) and touch sensitive layer (211) may act against parallax issues, which may be of particular concern with a display panel (201) having a compound curved exterior surface (203) and a flat interior surface (202) like that of FIG. 19. Other methods of affixing the touch sensitive layer to the interior surface may also be used. Another such example is using double sided tape as a cost saving option, albeit without achieving the same advantages as optical bonding.

The touch sensitive layer (211) may also have a high transmission ratio so as to limit deleterious effects of transmission of optical output (210) from the display output device (209) through the display assembly (200) to be viewed on the display zone (204), such as a touch sensitive layer (211) with a transmission ratio of about 85% to about 95%. In an example embodiment a touch sensitive layer (211) with a transmission ration of about 88% has achieved good results.

Optical bonding (225) may also be used between the touch sensitive layer (211) and the display output device (209). In the example embodiment of FIG. 19, however, the flat touch sensitive layer (211) is joined with the display output device (209) simply using double sided tape. Such an arrangement has been found to produce acceptable results for attaching these two components of the dead front display assembly (200), and may simplify manufacture.

The display output device (209) may be a flat LCD TFT panel. It has been found that using a display output device (209) with a illumination module (221) producing a backlight luminance of less than about 2000 nits surprisingly produces good results for a dead front display using a low transmissivity film (223). Backlight illuminance of about 1400 nits to about 1600 nits, or about 1500 nits has been used to provide an effective dead front display effect on a display zone (204) having the IMD film (225) simulating steel as described hereinafter or about 1500 nits.

It has been surprisingly found that an effective dead front display zone (204) can be formed using a material with a low transmittance ratio as well as a reflective surface quality. For example a film (223) having a transmission ratio of between about 10% and 40% may be used.

In a preferred embodiment, the display zone (204) and any non-display portions (208) of the display assembly (200) may have present as a metallic material in the ambient unenergized state. This may be advantageous as many kitchen appliances (1) have a metallic construction such as stainless steel. In this manner having a dead front display zone (204) simulating the same metallic visual character as adjacent parts of the outer housing (101) greatly enhances the dead front character of the display zone (204) looking like an ordinary part of the outer housing (101) in the unenergized state, and the visual display information (207) being seemingly presented on an ordinary metallic part of the outer housing (101) with the display output device (209) within the outer housing (101) substantially undiscernible.

However, a dead front display assembly (200) with a display zone (204) having a stainless steel character may be thought to be unsuitable, as polished and even brushed steel are prone to surface reflections that may obscure any visual display information (207) on the display zone (204), and attempting to increase the brightness of the visual display information (207) by increasing illuminance of the back light (221) may result in black space of the display output device (209) becoming visible on the display zone (204), thus diminishing the dead front effect. Furthermore, the conductivity of metal surfaces would not seem to support use of a capacitive touch sensitive layer (211), and metallic looking finishes may be thought as having such low transmittivity so as to be unsuitable for a dead front style display.

In the embodiments described herein a semi-transparent film (223) applied to the exterior surface (203) of the display panel (201) with a finish sympathetic to the industrial design of the kitchen appliance (1) by replicating surrounding finishes, and which allows for an effective dead front display zone (204). In particular, the film (223) may have a metal finish. The film (223) material may comprise a non-conductive in mold decoration (IMD). The IMD may be applied to a PMMA or nylon substrate, or any other suitable material. If the a touch sensitive layer is to be used A metal simulating ink may be used. The material may be formed by a roll-on hot stamping process.

Effective dead front display assemblies (200) have been produced using such metallic looking films (223) having transmission ratios of about 10%-40% using a backlight (221) illuminance of less than 2000 nits and in the order of about 1500 nits. In one non-limiting example, effective results have been achieved using a metallic looking film (223) with a transmission ratio of about 28% and a TFT LCD display output device (209) with a back light (221) luminance of about 1500 nits. This arrangement used an embodiment similar to FIG. 19 where the optical bonding (225) adhesive has a transmission ratio of about 92% and the touch sensitive layer (211) had a transmission ratio of about 89%. It has been found through extensive experimentation that the target luminance on the display zone (204) is about 200 to 400 nits when a metallic simulating film (223) is used, with a target luminance of about 250nits offering good results.

The curved exterior surface (203) of the display panel (201) is desirable, as the very nature of dead front style displays involve seemingly seamless integration with surround parts of the kitchen appliance (1), such that the display zone (204) seemingly disappears when unenergized in an ambient state. As industrial design of kitchen appliances (1) typically involve contoured surfaces, similarly curved dead front displays (204) are required to blend in, which would not be the case for a flat dead front display zone (204).

However, certain challenges are encountered when pursuing a cost effective dead front display assembly (200) with a curved outer surface (203), such as issues with manufacturing defects potentially affecting optical quality as hereinbefore described.

Furthermore, due to the provision of a flat interior surface (202) to advantageously use a flat touch sensitive layer (211) as herein described, the display panel (201) will have variable wall thickness between the interior surface (202) and exterior surface (203) across its transverse extent. If the exterior surface (203) features compound curvature like that of example embodiment FIG. 19, the wall thickness may vary in both the perpendicular x and y transverse directions.

Varying wall thickness may present certain challenges beyond manufacturing defects as hereinbefore described. For example, the varying thickness between the flat interior surface (202) and the curved exterior surface (203) may cause distortion of the optical output (210) travelling from the visual display device (209) through to the display zone (204).

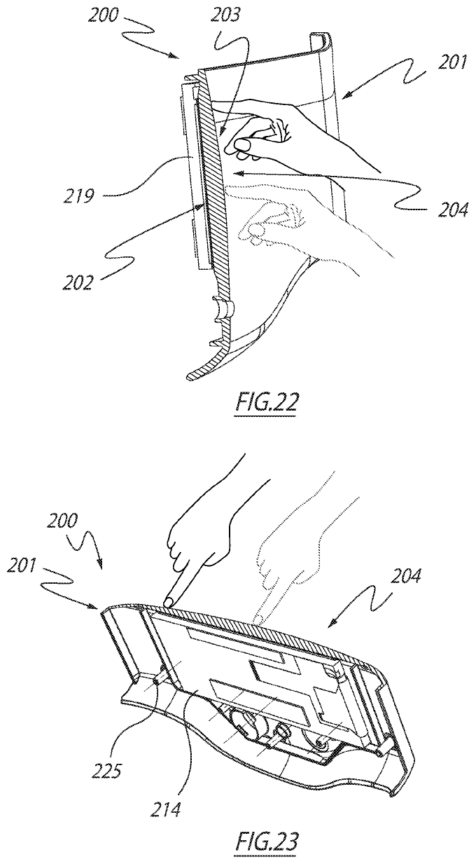

The varying thickness between the flat interior surface (202) and the curved exterior surface (203) may also cause issues with the sensitivity of the flat touch sensitive layer (211) which utilizes electrical properties of the human body or specialized input device such as a stylus for input. This effect may be seen in FIGS. 22 and 23 showing the touch sensitive layer (211) reading electric properties of a human finger through differing wall thicknesses at different transverse points, which may cause frustrating imprecision when using the touch screen.

It has been found that limiting the extent of the curvature can produce a dead front display assembly (200) having contours that blend with surrounding portions of the kitchen appliance (1) and outer housing (101), but mitigates the deleterious effects and disadvantages to acceptable degrees. For example, limiting the ratio of variance between wall thickness across the transverse direction to about 0.025 has been found to offer a suitable compromise. A variance ratio of 0.025( 1/40) represents the wall thickness between two transverse points 40 mm apart varying by 1 mm.

FIG. 24 shows a schematic cutaway of the display panel of FIG. 19. In this non-limiting example embodiment, the thickness between the interior surface (202) and the exterior surface (203) plus the film (223) is about 4 mm at the centre of the display zone (204) and reduces to a thickness of about 1.8 mm at the edge of the display zone (204) 100 mm away in the horizontal transverse direction. This corresponds to a variance ratio of about 0.022, such that the wall thickness reduces by about 1 mm between two points separated by about 46 mm in the horizontal direction. The radius of this curvature can be considered as about R3000mm.

The thickness between the interior surface (202) and the exterior surface (203) plus the film is about 4 mm at the centre of the display zone and reduces to a thickness of about 3.2 mm at the edge of the display zone 66 mm away in the vertical transverse direction. This corresponds to a variance ratio of about 0.012, such that the wall thickness reduces by about 1 mm between two points separated by about 83 mm in the horizontal direction. The radius of this curvature can be considered as about R100,000 mm.

It has been surprisingly found that the slight curvature of the dead front display zone (204) may have an advantageous effect on the viewability of visual display information (207). This advantageous effect may be particularly notable when the display zone (204) has a metallic looking finish, such as those hereinbefore described. However, this advantageous effect may also be experienced with other surface finishes, for example a glossy plastic finish. Specifically, the curved display zone (204) may act to diffuse reflections, making the visual display information more readily discernible from the reflective display zone (204). Such reflections may otherwise require use of more powerful illuminance modules (211), adding extra cost and increasing the likelihood of parts of the display output device (209) becoming greyed-out and therefore visible on the display zone (204) when not desired, which may reduce the dead front effect.

Furthermore, if a user is having any difficulty discerning visual display information (207), the deleterious effect of the reflections may be overcome by making only a slight adjustment to their viewing position than may be the case compared to a flat display zone (204) having less diffuse reflections. As ambient lighting causing reflections may not be adjustable in a user's kitchen, and bench space for positioning the appliance is often very limited, being able to make a small adjustment to viewing position to avoid reflections obscuring the visual information (207) may be particularly advantageous in this application.

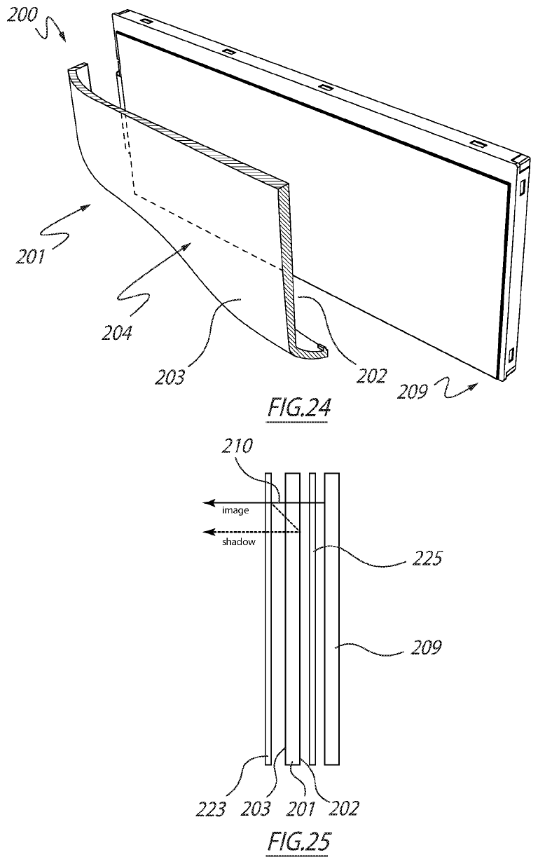

In certain embodiments involving the use of a reflective outer film (223), a doubling of the visual display information may be encountered at certain viewing angles, with an offset low brightness shadow or phantom of the visual display information (207). Without wishing to be bound by theory, it is though that this phenomenon may be caused by a portion of the optical information being internally reflected by the film (223) and then reflected back from another component such as the display panel (201). FIG. 25 shows a schematic representation of this phenomenon.

Several solutions to this problem have been identified. The polymer used to form the dead front panel may be tinted prior to molding in order to reduce the transmission ratio. Similarly the optical bonding (225) resin may be tinted in order to reduce the transmission ratio. To account for these lower transmission ratios, the back light (221) illuminance may be increased to achieve the desired illuminance of visual display information on the display zone (204)

It is to be understood that any of the exemplified features discussed in relation to a specific embodiment is not to be taken as limited for use with that embodiment only. The person skilled in the art having read this disclosure as a whole would readily be able to identify advantageous features discussed in one embodiments as having utility with another embodiment using their ordinary ability. For example, any embodiment may use a touch sensitive layer with haptic feedback, or employ the metallic simulating IMD film, or have a display zone with another ambient appearance, for example, by use of black plastic to form the display panel, such as glossy black plastic. Any of the embodiments can be combined with sensors such as ambient light sensors or motion sensors in the manner described, or may alternatively employ a voice sensor to energise the optical output device or otherwise change the operating state of the display output device. Any of the embodiments may be configured to present options for selection on the display zone, then upon selection, present other indicia related to that selection.

Although the above embodiments have been described in relation to a dead front style display, the disclosure can be applied to non-dead front displays. For example, the display panel can be configured so as not to appear opaque when the display output device is not energized as would normally be the case where a display output device is mounted internal within the outer housing. While such an embodiment would not be endowed with the advantages relating to a dead front style display as disclosed herein, it would still be endowed with the other advantages disclosed herein. For Example, the embodiment of FIG. 19 could be provided as a non-dead front display by selection of the display panel material and/or the outer film/coating, or by merely omitting a dead front coating, depending on the specifics of manufacture. Such an assembly would still have the advantages of a curved exterior surface as disclosed herein, while still allowing for touch sensitive capability by provision of the flat interior surface as well as the wall thickness variation ratios.

Unless specified otherwise reference to a curved surface refers to any type of curved surface, including a conic curved surface like a cylinder curved in one direction, or a compound curved surface (like a sphere curved in two directions). While certain embodiments are described in relation to a specific curvature, such examples are not to be understood as limiting to the disclosure of the invention, and the person skilled in the art could readily adapt the teaching herein to different curved surfaces, for example, adapting an embodiment with a conic curved surface into a compound curved surface and vice versa.

For the avoidance of doubt, as a matter of brevity, reference to the display panel and/or the exterior surface may or may not be inclusive of any outer film, which is believed to be clear from the context of use as would be readily apparent to the person skilled in the art.

In an embodiment, the kitchen appliance (1) may include a sensor (222) to measure the ambient brightness of the room and adjust control the illumination module (221) to control the brightness of the visual display information (207) exhibited on the display zone (204).

Although the invention has been described with reference to specific examples, it will be appreciated by those skilled in the art that the invention may be embodied in many other forms. By way of non-limiting example, the invention may be applied to any suitable kitchen appliance, including microwave ovens, kettles, toasters, conventional ovens and refrigeration devices.

As used herein, unless otherwise specified, the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other matter.

Reference throughout this specification to “one embodiment” or “an embodiment” or “example” means that a particular feature, structure or characteristic described in connection with the embodiment is included in at least one embodiment of the present invention. Thus, appearances of the phrases “in one embodiment” or “in an example” in various places throughout this specification are not necessarily all referring to the same embodiment or example, but may, Furthermore, the particular features, structures or characteristics may be combined in any suitable manner, as would be apparent to one of ordinary skill in the art from this disclosure, in one or more embodiments.

Similarly it should be appreciated that in the above description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Any claims following the Detailed Description are hereby expressly incorporated into this Detailed Description, with each claim standing on its own as a separate embodiment of this invention.

Unless specifically stated otherwise, as apparent from the following discussions, it is appreciated that throughout the specification discussions utilizing terms such as “processing,” “computing,” “calculating,” “determining” or the like, refer to the action and/or processes of a microprocessor, controller or computing system, or similar electronic computing or signal processing device, that manipulates and/or transforms data.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Thus, while there has been described what are believed to be the preferred embodiments of the invention, those skilled in the art will recognize that other and further modifications may be made thereto without departing from the scope of the invention, and it is intended to claim all such changes and modifications as fall within the scope of the invention.

While the present invention has been disclosed with reference to particular details of construction, these should be understood as having been provided by way of example and not as limitations to the scope of the invention.

In the foregoing description of preferred embodiments, specific terminology has been resorted to for the sake of clarity. However, the invention is not intended to be limited to the specific terms so selected, and it is to be understood that each specific term includes all technical equivalents, which operate in a similar manner to accomplish a similar technical purpose. Terms such as “front” and “rear”, “above” and “below” and the like are used as words of convenience to provide reference points and are not to be construed as limiting terms.

### PARTS LIST

Kitchen Appliance 1
   body 100
   outer housing 101
   display assembly 200
   display panel 201
   interior surface of display panel 202
   exterior surface of display panel 203
   display zone 204
   main display zone 205
   secondary display zone 206
   visual display information 207
   non-display portion 208
   display output device 209
   optical output 210
   touch-sensor layer 211
   proximity sensor 212
   chassis 213
   interior-facing surface of chassis 214
   exterior-facing surface of chassis 215
   recess in chassis 216
   perimeter of exterior-facing surface of chassis 217
   aperture in chassis 218
   display output device support bracket 219
   adhesive layer 220
   illumination module 221
   ambient light sensor 222
   outer film 223
   secondary feature 224
   optical bonding 225

1. A kitchen appliance comprising a dead front display assembly, the assembly comprising:
a display panel having an exterior surface featuring a display zone for presenting visual display information from optical output of a display output device, wherein at least a portion of the exterior surface of the display panel comprises a curved surface, and at least a portion of the interior surface is planar.

2. The kitchen appliance according of claim 1, wherein said display zone has one or more of: a low transmission ratio, a highly reflective visual characteristic, or a metallic ambient appearance when not displaying visual display information.

3. The kitchen appliance of claim 2, wherein the low transmission ratio, a highly reflective visual characteristic, or a metallic ambient appearance when not displaying visual display information is provided by a coating on an exterior surface of the display panel.

4. The kitchen appliance of claim 3, wherein the coating is a non-conductive in mold decoration (IMD) film or a hot stamped film.

5. The kitchen appliance of claim 4, wherein the coating has a transmission ratio of about 10% to about 40%, and has an ambient appearance simulating stainless steel.

6. The kitchen appliance of claim 1, wherein the display panel thickness varies transverse along the display zone perpendicular to the thickness dimension by a ratio of equal or less than about 0.025.

7. The kitchen appliance of claim 1, wherein the exterior surface had a compound curvature, and wherein the display panel thickness varies along a first perpendicular transverse direction of the display zone by a ratio of about 0.02, and along a second perpendicular transverse direction of the display zone by a ratio of about 0.01.

8. The kitchen appliance of claim 1, further including a touch sensitive layer applied to the planar interior surface.

9. The kitchen appliance of claim 8, wherein the touch sensitive layer is flat and substantially rigid.

10. The kitchen appliance of claim 8, wherein the touch sensitive layer is optically bonded to the interior surface.

11. The kitchen appliance of claim 10, wherein tinted resin is used for optical bonding.

12. The kitchen appliance of claim 1, wherein brightness of the display zone is configured as between about 150 nits to about 500 nits.

13. The kitchen appliance of claim 1, wherein brightness of the display zone is configured about 250 nits.

14. The kitchen appliance of claim 1, wherein the optical display device has a backlight illuminance of less than about 2000 nits.

15. The kitchen appliance of claim 1, further including a chassis having secondary features for supporting the display panel.

16. The kitchen appliance of claim 15, wherein the secondary features include one or more of supporting ribs or screw tubes.

17. The kitchen appliance of claim 15, wherein clip features are used to removably attached the chassis to the display panel.

18. The kitchen appliance of claim 1, wherein the display zone has an appearance simulating surrounding portions of the kitchen appliance.

19. The kitchen appliance of claim 1, wherein the display zone has a first state without any visual display information from the display output device; a second state where the visual display information includes an indicia representing a power on operation; a third state with visual display information showing selectable modes of operation; and fourth state with the visual display information relating to the selected mode of operation.

20. A dead front display assembly for a kitchen appliance as defined in claim 1.

21-22. (canceled)
